(19) United States
(12) Patent Application Publication
(10) Pub. No.: US 2018/0308966 A1
(43) Pub. Date: Oct. 25, 2018

(54) FIELD-EFFECT TRANSISTOR WITH OPTIMISED PERFORMANCE AND GAIN

(71) Applicants: THALES, COURBEVOIE (FR); COMMISSARIAT A L'ENERGIE ATOMIQUE ET AUX ENERGIES ALTERNATIVES, PARIS (FR)

(72) Inventors: Jean-Claude JACQUET, ORSAY (FR); Piero GAMARRA, PALAISEAU (FR); Stéphane PIOTROWICZ, MAGNY LES HAMEAUX (FR); Cédric LACAM, MONTROUGE (FR); Marie-Antoinette POISSON, PARIS (FR); Olivier PATARD, PARIS (FR)

(21) Appl. No.: 15/769,708

(22) PCT Filed: Oct. 27, 2016
(86) PCT No.: PCT/EP2016/075971

§ 371 Date: Apr. 19, 2018

(30) Foreign Application Priority Data
Oct. 30, 2015 (FR) 1502296

(51) Int. Cl. H01L 29/778; H01L 29/20; H01L 29/205

(52) U.S. Cl. CPC H01L 29/7783; H01L 29/205; H01L 29/2003

(57) ABSTRACT

A transistor comprises a stack of semiconductor materials including, in particular, a first sub-layer, carefully arranged and with a specific thickness, splitting the buffer layer into two portions and including a third material so that the difference in the piezoelectric and spontaneous polarisation coefficients between the material of the buffer layer and the third material induces, at a first interface between the first portion of the buffer layer and the first sub-layer, a first fixed surface electric charge generating an electrical field directed along the axis z so as to follow the two-dimensional gas to be contained in the channel.

The present invention relates to high-electron-mobility field-effect transistors (HEMTs).

The present invention more particularly relates to the stacks from which HEMTs that are used as power or low-noise amplifiers, as switches or as oscillators, and that cover the frequency range typically comprised between 1 MHz and 100 GHz, are fabricated.

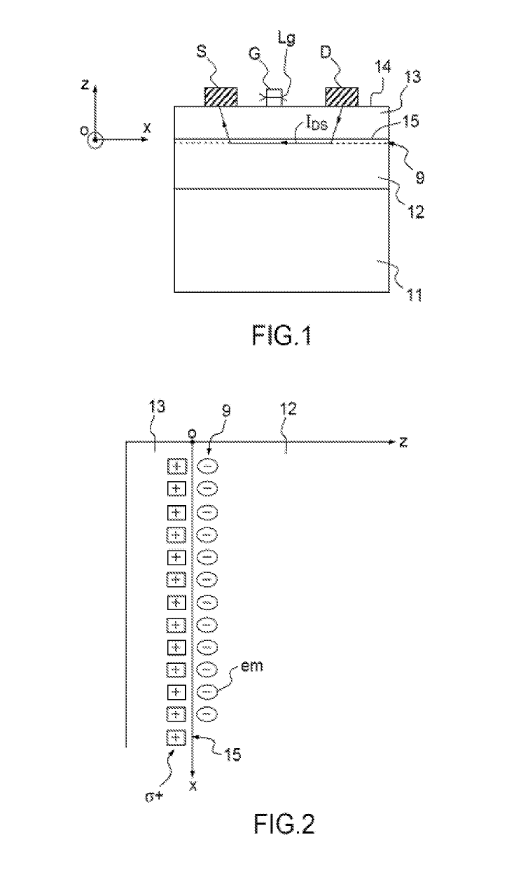

FIG. 1 schematically shows a cross section of the structure of a conventional elementary HEMT system in an Oxz-plane, said system being produced on a substrate 11. Conventionally, a semiconductor or insulating substrate 11 (for example comprising silicon (Si), silicon carbide (SiC) or sapphire (Al₂O₃)) is used, on which a stack Emp of at least two semiconductor layers that extend in the Oxy-plane is produced, along the z-axis.

A first layer 12, called the buffer layer, has a large bandgap, wide bandgap semiconductors being spoken of, some such semiconductors comprising a binary compound (such as GaN) or a ternary III-nitride compound (such as AlGaN, or more precisely AlₓGa₁₋ₓN), these also being referred to as III-N compounds.

A second layer, called the barrier layer 13, has a larger bandgap than that of the buffer layer 12. This layer comprises a semiconductor based on a quaternary, ternary or binary III-nitride (III-N) compound based on Al, Ga, In or B.

For example, with a buffer layer 12 made of GaN, the barrier layer 13 comprises AlₓGa₁₋ₓN or In₁₋ₓAlₓN, or an In₁₋ₓAlₓN/AIN or AlₓGa₁₋ₓN/AIN sequence. Depending on the aluminum content x, the size of the bandgaps of AlₓGa₁₋ₓN and In₁₋ₓAlₓN vary from 3.4 eV (GaN) to 6.2 eV (AlN) and from 0.7 eV (InN) to 6.2 eV, respectively.

The thickness of the barrier layer 13 is typically comprised between 5 nm and 40 nm, and the thickness of the buffer layer 12 is typically comprised between 0.2 μm and 3 μm.

Additional layers may be present either on the surface of the stack, or between the buffer layer 12 and the barrier layer 13.

The buffer layer 12 and the barrier layer 13 are conventionally produced by metal organic vapor phase epitaxy (MOVPE) or molecular beam epitaxy (MBE). By way of example, mention may be made of a buffer layer 12 based on GaN with a barrier layer 13 based on AlGaN or InAlN, and more precisely based on AlₓGa₁₋ₓN or In_{z}Al_{1-z}N, with x typically comprised between 15% and 35%, and, z typically comprised between 15% and 25%.

The junction between the buffer layer 12 and the barrier layer 13 forms a heterojunction 15 that also extends in the Oxy-plane. The origin O of the coordinate system Oxyz is chosen to lie in this plane.

A HEMT conventionally comprises a source S, a drain D and a gate G that are deposited on the top side 14 of the barrier layer 13.

The gate G is deposited between the source S and the drain D and allows the transistor to be controlled.

The current between the source S and the drain D is modulated via the electrostatic action of the gate G (which is conventionally of Schottky or MIS type, MIS standing for metal/insulator/semiconductor) on the two-dimensional electron gas 9 (2DEG) that is confined to the vicinity of the heterojunction 15. The voltage V_{GS} applied between the gate G and the source S controls the current flowing through the transistor.

These electrons are mobile in the Oxy-plane and have a high electron mobility μe, typically higher than 1000 cm²/Vs. In normal operation, these electrons are unable to flow in the z-direction because they are confined to the potential well that forms in the Oxy-plane in the vicinity of the heterojunction 15. The electron gas 9 confined to what is called the channel of the transistor is therefore able to transport a current I_{DS}, this current flowing between the drain D and the source S. Conventionally, a potential difference V_{DS} is applied between the source S and the drain D, typically with a source S connected to ground, and the value of the current I_{DS} is a function of the voltage V_{GS} applied between the gate G and the source S.

The transconductance gₘ of a transistor is defined as the ratio between the current I_{DS} and the voltage V_{GS}. In other words, the transconductance expresses the variation in the drain current as a function of the bias of the gate V_{GS}, at constant V_{DS}.

The gain of the transistor is related to its transconductance. Gain increases proportionally to transconductance gₘ, allowing a weak signal applied to the gate G to be converted into a stronger signal on the drain D.

FIG. 2 shows the charge distribution in the vicinity of the heterojunction 15. The semiconductors of the III-N family are highly electronegative. When two different compounds of this family are placed in contact, positive σ+ or negative σ− fixed electrical charges of piezoelectric nature appear at the interface, such as shown in FIG. 2. The resulting fixed surface electric charge attracts movable charges: electrons when it is positive such as in FIG. 2 or holes when it is negative. It is these mobile charges em that create a current when a voltage is applied between the drain D and the source S.

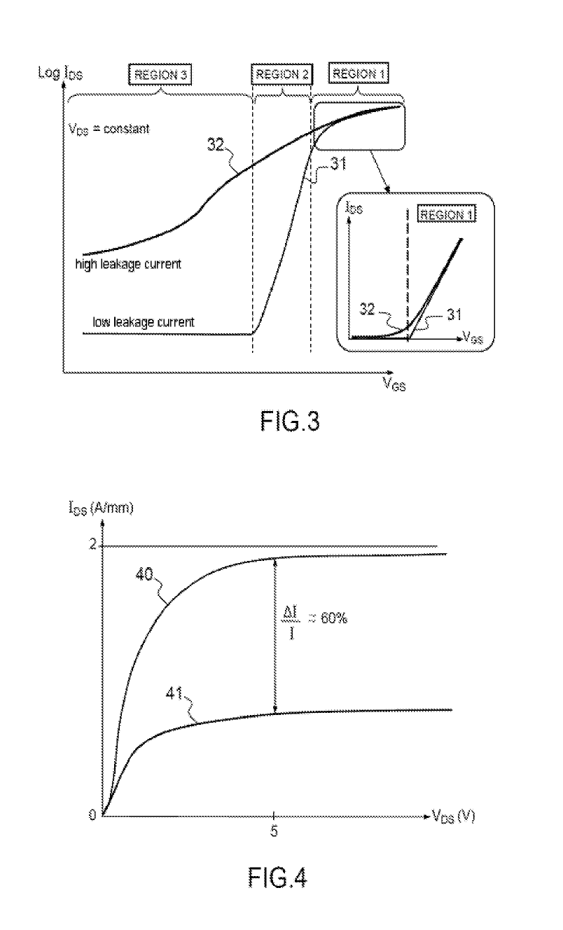

GaN is a semiconductor that, under conventional growth conditions, is doped with donor-type (n-type) impurities, typically nitrogen vacancies. This type of defect does not allow electrons to be effectively confined to the channel when the voltage applied to the drain of the transistor becomes too high, typically higher than 10 V, and when the length of the gate Lg becomes too short, typically shorter than 0.25 μm. The electrons then flow through the buffer layer 12, this causing:
a decrease in the transconductance gₘ and therefore in the gain of the transistor (region 1 of FIG. 3);
an increase, in the exponential zone of the transfer curve (region 2 of FIG. 3) in the subthreshold swing (SS=n(k_{b}T/q)log(10)). This quantity, which is expressed in mV/decade, corresponds to the variation in the gate voltage necessary to increase the current by one decade. At room temperature and in the ideal case in which n=1, it is equal to 60 mV per decade. The degradation of this quantity decreases the ability of the component to switch a current;
an increase in the leakage current and therefore a decrease in the efficiency of the transistor (region 3 of FIG. 3).

Ineffective confinement therefore has direct repercussions on the performance of the transistor, as may be seen in FIG. 3.

FIG. 3 is a graphical representation of log(I_{DS})=f(V_{GS}) for a transistor exhibiting good and poor confinement of electrons.

Three regions may be defined therein.
The region 1 in which the transconductance gₘ is defined and in which the graphical representation of IDs as a function of V_{GS} associated with the curve log(I_{DS})=f(V_{GS}) contains a substantially linear section.
The region 2 corresponds to the zone that is preferentially used in switching applications and, in particular, to the zone in which the transfer characteristics of a transistor are defined. The subthreshold swing SS is defined in this region.
The region 3, corresponds to an asymptotic zone in which the leakage current may be defined.

The curve 31 of FIG. 3 corresponds to the graphical representation of log(I_{DS})=f(V_{GS}) for a transistor exhibiting a good confinement of electrons to the channel. At high constant V_{DS}, 20 V for example, and for a gate length shorter than 0.25 μm, for example, the curve 31 has a high transconductance gₘ, a subthreshold swing SS that is close to its ideal value of 60 mV/decade at room temperature and a low leakage current, typically lower than 100 μA/mm.

The curve 32 of FIG. 3 corresponds to the graphical representation of log(I_{DS})=f(V_{GS}) for a transistor exhibiting a poor confinement of electrons to the channel.

To obtain a good confinement of electrons to the channel and to obtain a good transistor performance in terms of gain, subthreshold swing SS and electrical efficiency, it is necessary to compensate for the initial n-doping.

A first solution is to p-dope the buffer comprising GaN or AlₓGa₁₋ₓN by introducing acceptor-type impurities, for example by modifying the epitaxial growth conditions or by adding acceptor-type impurities during the growth of the layer.

The impurity density introduced into the entirety of the buffer layer 12 is optimized to obtain the desired transistor behavior. Compatible impurities are mainly carbon and iron but may also be magnesium, beryllium or zinc or any impurities known to be an acceptor center in GaN. Typically, an excess of p-type impurities with respect to the n-type impurities of 10¹⁶ cm⁻³ to 10¹⁷ cm⁻³ allows the subthreshold swing to be kept at a value lower than 150 mV/decade for a maximum operating voltage V_{DS} of 50 V and a gate length Lg of 0.15 μm. However, these impurities form deep centers.

The expression “deep center” is employed to refer to an impurity the energy level of which is located at more at than 2 to 3 times the thermal activation energy (3/2 k_{b}T) from the minimum of the conduction band for an n-type impurity or from the maximum of the valence band for a p-type impurity. At room temperature, the thermal activation energy is about 40 meV.

A center is therefore considered to be deep when it is located at more than 100 meV from one of these extrema, this being the case for GaN doped with acceptor-type impurities. The centers charge negatively when the transistor is biased and, as they are deep, do not decharge at operating frequencies higher than one megahertz. This has the effect of decreasing the amount of mobile charge present in the conductive channel, this decreasing the current and increasing access resistance. It follows that the main drawback of this approach is, in addition to generating dispersion, that it decreases the efficiency of the transistor and the power that it is able to emit. This degradation in performance becomes increasingly pronounced as the operating voltage V_{DS} increases, the latter typically being higher than 20 V.

This decrease in mobile charge, which is referred to as current collapse, is illustrated in FIG. 4. In this example, the buffer layer of the GaN transistor is uniformly p-doped to a value of 5×10¹⁷ atoms/cm³.

The curve 40 is a current/voltage curve, taken at V_{GS}=0 V, of a transistor that was not biased prior to the obtainment of the curve.

The curve 41 is a current/voltage curve, taken at V_{GS}=0 V, of the transistor after it has undergone a stress taking the form of biasing with a voltage V_{GS}=−6 V and V_{DS}=40 V, prior to the obtainment of the curve.

It may be seen that in the curve 41 the variation in I_{DS} as a function of V_{DS} is modified with respect to the initial curve 40, the current/voltage characteristic being degraded. In this example, a relative decrease of 60% in the current I_{DS} and therefore in the available power is observed at a voltage V_{DS} of 5 V.

A second solution is to produce a composite GaN/AlₓGa₁₋ₓN buffer, for example, such as illustrated in FIG. 5, with the channel made of GaN.

In this case, the negative piezoelectric charge that appears at the GaN/AlₓGa₁₋ₓN interface 50 creates a potential barrier that allows electrons to be confined to the channel. A few percent of aluminum in the AlₓGa₁₋ₓN layer, typically 3% to 10%, are necessary to obtain a good confinement of the electrons for a maximum operating voltage comprised between 20 V and 40 V and a gate length shorter than 0.25 μm.

However, the thermal conductivity of AlₓGa₁₋ₓN is lower than that of GaN by a factor comprised between 3 and 5 for the aluminum contents necessary for a good electron confinement.

The thermal resistance of the transistor is thus greatly degraded (multiplied by 2 to 3) and the power that may be emitted is decreased by a factor of 1.5 to 3, depending on the application for which this solution is intended.

A first solution consists in introducing, into the buffer layer 12, just the right amount of fixed negative electric charge to achieve good transfer characteristics at the desired operating voltages and frequencies. Controlling the amount of charge and the position of the charges with respect to the electron gas 9 allows good confinement of the electrons to the channel to be obtained, without degrading the thermal conductivity of the buffer, which is for example made of GaN, and without creating undesirable trapping effects that lead to a degradation in linearity (or, in other words, dispersive effects) and to a decrease in the available power and efficiency.

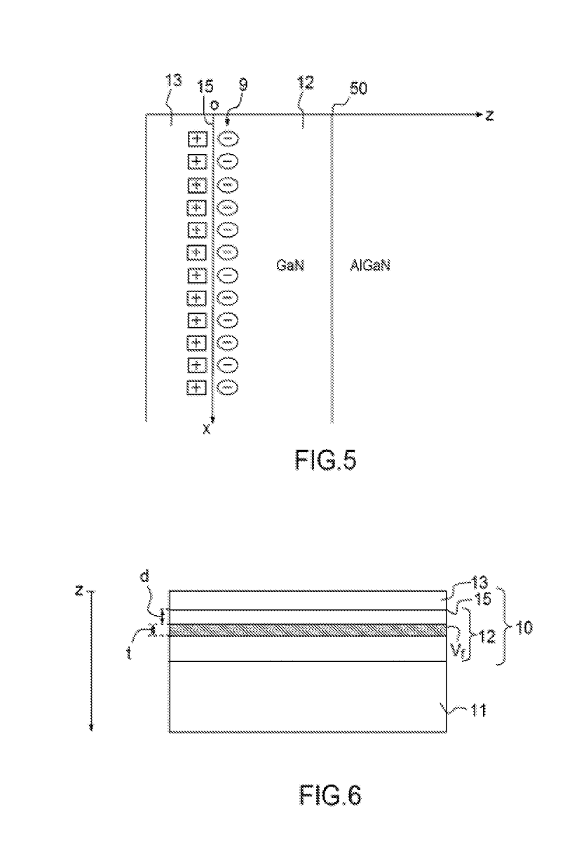

FIG. 6 illustrates a stack 10 for a high-electron-mobility field-effect transistor (HEMT) according to this third prior-art solution. The stack 10 is produced on a substrate 11 of a type conventionally used for this type of component.

The stack 10 comprises a plurality of layers in an xy-plane that is perpendicular to a z-axis.

The stack 10 comprises a buffer layer 12 comprising a first “wide bandgap” semiconductor such as AlGaN, and more precisely AlₓGa₁₋ₓN, with x typically comprised between zero and 35%. The buffer layer 12 of the stack comprises a zone Vf comprising fixed negative charges that are confined to a specific location of the buffer layer 12.

The expression “fixed negative charges” is understood to mean charges that are non-mobile (mobile charges in this context means electrons or holes), the term mobile being understood in its conventional sense in the field of the physics of semiconductors.

The zone Vf extending in the xy-plane is located at a distance d from the heterojunction and has a thickness t.

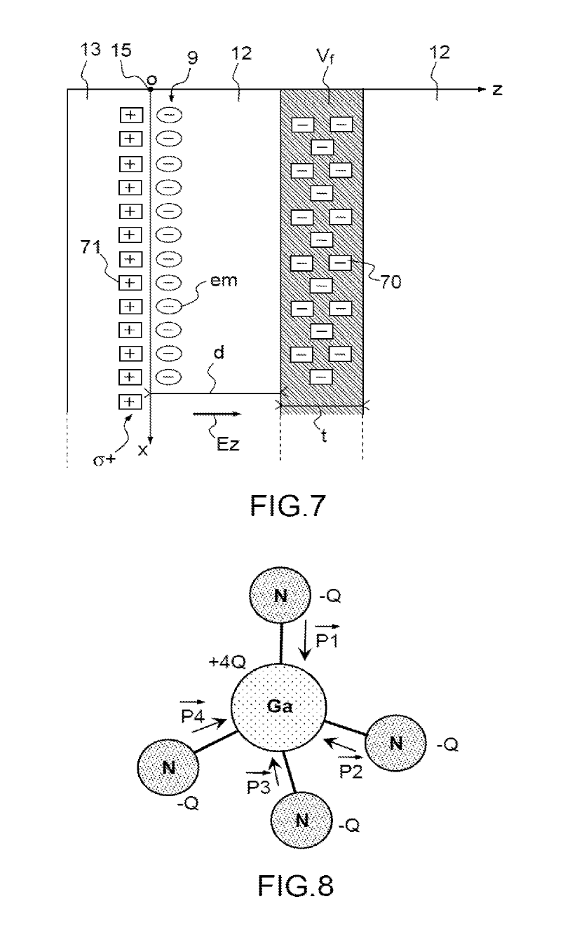

FIG. 7 describes, more precisely, the distribution and the nature of the charges in the stack. The fixed character of a charge is symbolized by a frame of rectangular shape encircling this charge, whereas a mobile character is symbolized by a frame of oval shape. As described above, because of a piezoelectric effect, a surface density σ+ of fixed positive charges 71 is present in the vicinity of the heterojunction 15, and mobile negative charges em, which are also located in proximity to the heterojunction 15, form the two-dimensional electron gas 9 that is the origin of the operation of the HEMT. The electron surface density em in the channel is typically about 0.5×10¹³ to 3×10¹³ cm⁻².

The charge profile that it is necessary to produce (location and dose of the negative charges) to obtain a good electron confinement depends on the operating voltage, on the gate length and on the electron density in the channel of the transistor. In other words, for each operating voltage V_{DS}, the gate length, electron density and fixed charge profile must be optimized.

The fixed negative bulk electric charges 70 located in the buffer layer 12 are obtained from acceptor-type impurities A (such as atoms of carbon, iron, magnesium or any type of impurities known to be an acceptor center in GaN or AlGaN) that are introduced into the buffer layer 12.

One aim of the invention is in particular to provide a transistor intended for fast-switching (envelope modulation), microwave-signal power amplification applications having a good thermal conductivity and the configuration of the buffer layer of which is dependent of the conditions of use.

According to one aspect of the invention, a field-effect transistor is provided, said transistor comprising a stack along a z-axis, comprising:
a barrier layer comprising a first semiconductor;
a heterojunction between said barrier layer and a buffer layer; and
a two-dimensional gas confined to a channel located in an xy-plane that lies perpendicular to the z-axis and in the vicinity of the heterojunction,
the buffer layer comprising a second semiconductor comprising a quaternary or ternary or binary nitride compound,
characterized in that the stack furthermore comprises a first sublayer that divides the buffer layer into two portions and that comprises a third semiconductor comprising a quaternary or ternary or binary nitride compound, so that the difference between the piezoelectric and spontaneous polarization coefficients of the second semiconductor and the third semiconductor induces, at a first interface between the first portion of the buffer layer and the first sublayer, a first fixed surface electric charge that generates an electric field that is directed along the z-axis and that is oriented toward the first interface, so as to allow the two-dimensional gas to be confined to the channel, the distance between the heterojunction and the first interface that is located between the first portion of the buffer layer and the first sublayer being comprised between one third of the length of the gate in the direction Ox perpendicular to the direction Oz of the stack of the transistor and two times the gate length, the thickness of the first sublayer along the z-axis being smaller than a threshold value. Advantageously, the threshold value of the thickness is 20 nm.

The profile of this stack Emp allows mobile charges to be better confined to the channel.

Advantageously, the two-dimensional gas is an electron gas, the fixed surface electric charge induced at the first interface between the first portion of the buffer layer and the first sublayer being negative and thus generating an electric field that is oriented toward the first sublayer and confines the electrons to the channel.

Advantageously, the second semiconductor is AlₓGa₍₁₋ₓ₎N with x=0%.

Advantageously, the first sublayer comprises Alₓ₁Ga₍₁₋ₓ₁₎N, x₁ being higher than x+15%, x being the aluminum content of the buffer layer and x₁ being the aluminum content of this first sublayer.

Advantageously, the buffer layer furthermore comprises a second sublayer that is located between the first sublayer and the second portion of the buffer layer, the second sublayer comprising Alₓ₂Ga₍₁₋ₓ₂₎N, x₂ being lower than or equal to x+15% and higher than or equal to x, x being the aluminum content of the buffer layer and x₂ being the aluminum content of this second sublayer, generating an excess of negative fixed electric charges at a second interface from the heterojunction, between the first and second sublayer, and a second fixed surface electric charge that is positive and lower, in absolute value, than the first fixed surface electric charge of the first interface.

Advantageously, the thickness of the second sublayer in the direction of the stack is larger than or equal to 100 nm.

Advantageously, the second AlGaN sublayer has an aluminum concentration gradient that increases in the direction of the stack and that is oriented toward the heterojunction, the aluminum concentration x₂ at the interface between the sublayers 19 and 12b being comprised between x and x+15%.

The association of a second sublayer comprising AlGaN in particular allows the formation of an electron gas in the vicinity of the second interface between the first sublayer and the second portion of the buffer layer to be avoided.

The aluminum concentration gradient allows the degradation of the thermal resistance of the transistor generated by the addition of the second sublayer to be limited.

Advantageously, the second sublayer furthermore comprises acceptor-type impurities so as to compensate for the n-type doping induced by the aluminum concentration gradient of the second sublayer.

Advantageously, the acceptor-type impurities introduced into the second sublayer are carbon or iron, beryllium or magnesium or beryllium or any type of impurity known to be an acceptor center in GaN or AlGaN.

Suitably placing a thin layer of material that generates an interface that is negatively charged (or, in other words, the sum of the surrounding charges of which is negative) allows mobile negative electric charges to be confined to the channel of the transistor.

The invention will be better understood and other advantages will become apparent on reading the following nonlimiting description, and by virtue of the appended figures, in which:

FIG. 1, which has already been mentioned, schematically shows a cross section of the structure of a conventional HEMT;

FIG. 2, which has already been mentioned, shows the charge distribution in the vicinity of the heterojunction of the conventional HEMT;

FIG. 3, which has already been mentioned, schematically shows characteristic current/voltage curves for a HEMT having a good and poor “pinch off”;

FIG. 4, which has already been mentioned, schematically illustrates the behavior of a prior-art HEMT exhibiting current dispersion;

FIG. 5, which has already been mentioned, schematically illustrates a stack of a prior-art transistor having a composite buffer layer;

FIG. 6, which has already been mentioned, illustrates a stack for a prior-art field-effect transistor;

FIG. 7, which has already been mentioned, more precisely describes the structure of the charges in the prior-art stack;

FIG. 8 shows the charge distribution within a GaN crystal;

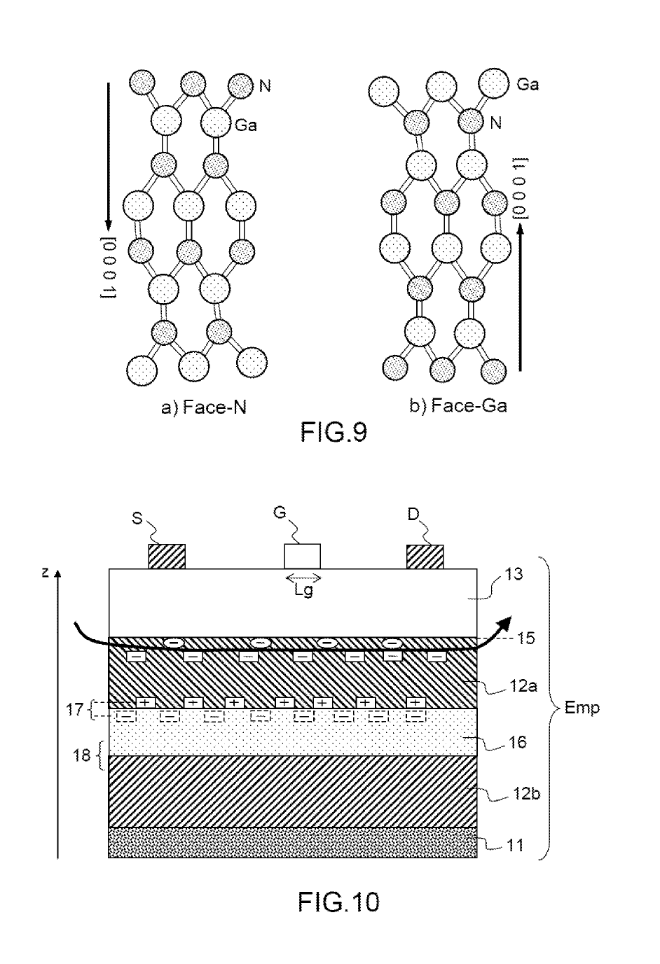

FIG. 9 illustrates two GaN wurtzite crystal structures;

FIG. 10 illustrates a transistor, according to one aspect of the invention;

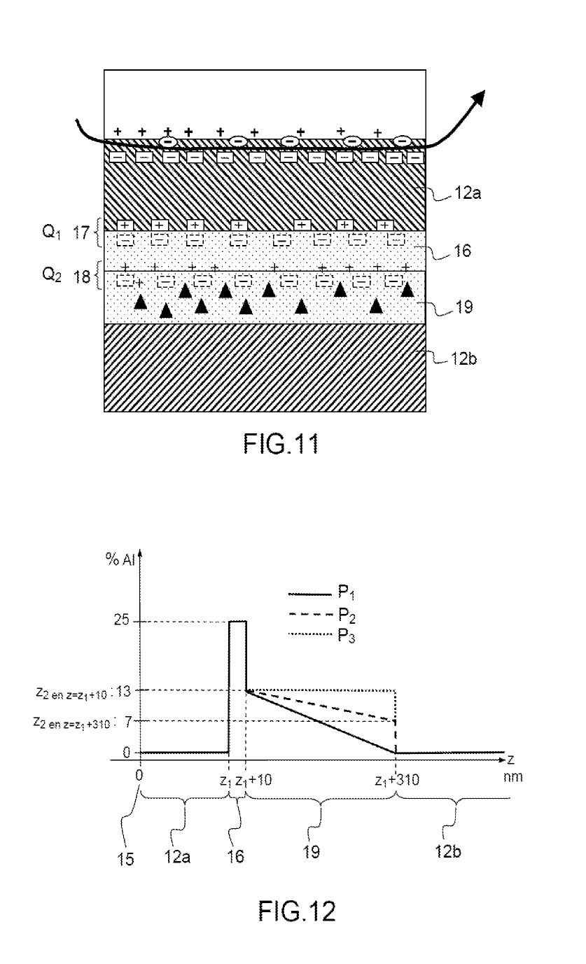

FIG. 11 shows a transistor according to another aspect of the invention;

FIG. 12 illustrates an example of a profile of the percentage of aluminum in the AlGaN of the stack, according to the invention. Three variants of the aluminum concentration profile of the layer 19 are shown (the aluminum concentration at the interface between the sublayers 16 and 19 being higher than or equal to the aluminum concentration at the interface between the sublayers 19 and 12b); and

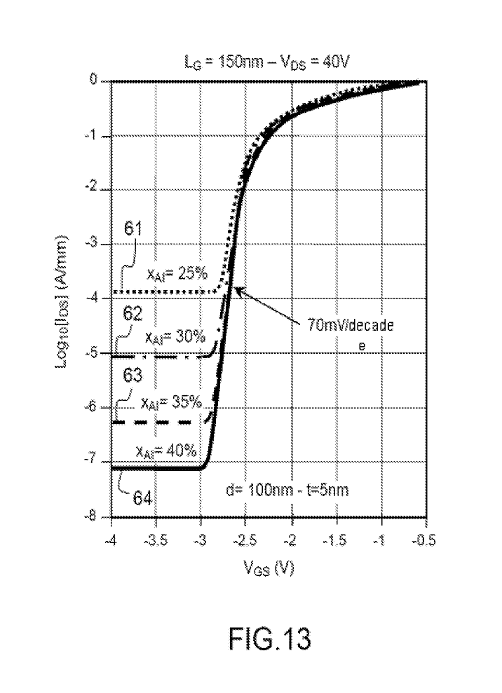

FIG. 13 shows simulated log(I_{DS})=f(V_{GS}) current-voltage characteristics of HEMTs according to the invention for various first-sublayer aluminum contents.

The principle of the invention consists in employing the intrinsic properties of the materials of the stack to confine the mobile charges that flow through the channel, rather than adding fixed charges (in the form of impurities) that must reflect the conditions of use of the transistor.

In a solid, the effects of polarization appear when the atoms of a crystal form dipoles that may or may not become partially or completely oriented under the action of an electric field.

In quaternary, ternary or binary semiconductors, because of the presence of atoms of different nature having different electronegativities, asymmetric molecules form, thereby creating permanent dipole moments. Semiconductors are easily subject to these polarization effects.

The polarization charges result from two mechanisms: spontaneous polarization and piezoelectric polarization.

Spontaneous polarization results from differences in the electronegativity of the various atoms making contact, and piezoelectric polarization results from mechanicals strains.

By spontaneous polarization, what is meant is the polarization of a molecule that is not subject to an electric field, and that is based on differences in the electronegativities of the atoms from which the molecule is composed. In the present case, the invention is based on the exploitation of these 2 types of polarization (spontaneous polarization and piezoelectric polarization) which are specific to this family of materials (i.e. the family of the III-Ns: association of elements of column III of the periodic table of the elements and of nitrogen: for example BN, GaN, AlN and InN are binary III-N compounds; AlGaN, InAlN, InGaN, BGaN are ternary III-N compounds; and InGaAlN is a quaternary III-N compound for example).

FIG. 8 illustrates the charge distribution within a GaN crystal.

Since gallium atoms are less electronegative than nitrogen atoms (electronegativities of 1.6 eV and of 3 eV, respectively) the electrons of the covalent bonds between these atoms have a higher probability of being closer to the nitrogen atoms. Thus, a negative charge coalesces around these atoms and a positive charge around the gallium atoms. The final charge distribution within a crystal results from the sum of the various contributions \vec{P1},\vec{P2},\vec{P3},\vec{P4}. The resultant of the polarizations \vec{P2}, \vec{P3},\vec{P4}, which is denoted, \vec{Pr}, is opposed to \vec{P1}. Calculations have shown that the contribution of \vec{P1} is larger than the contribution of the resultant \vec{Pr}, and therefore that the final spontaneous polarization is oriented in the same direction and has the same sign as \vec{P1}.

In the case where the oriented Ga—N bond ([0001] crystal direction) points toward the surface, Ga-face or gallium-polarity GaN is spoken of, and in the contrary case N-face or nitrogen-polarity GaN is spoken of.

In an N-face wurtzite structure a positive charge is generated at the surface and a negative charge of the same magnitude forms on the substrate side. The charge distribution is reversed in the case of a Ga-face wurtzite structure, as FIG. 9 shows.

Since the electronegativity of aluminum atoms is lower than that of nitrogen atoms, the sign and orientation of the electric field resulting from the spontaneous polarization are identical in the AlGaN layer and in the GaN layer.

FIG. 10 shows a transistor comprising a stack according to one aspect of the invention.

The stack 10 comprises a substrate 11, it also comprises a barrier layer 13 comprising a first semiconductor comprising a binary nitride compound, such as AlN, or a ternary nitride compound such as AlGaN or InAlN, and more precisely, AlₓGa₁₋ₓN or In_{y}A_{1-y}N with x typically comprised between 15 and 35%, or a quaternary nitride compound such as BAlGaN or InGaAlIN.

The stack 10 contains a heterojunction 15 between the buffer layer 12 and the barrier layer 13 and a two-dimensional electron gas 9 that is located in an xy-plane perpendicular to the z-axis and in the vicinity of the heterojunction 15, according to the conventional structure of a HEMT stack.

The buffer layer 12 furthermore comprises a first sublayer 16 that separates the buffer layer 12 into two portions 12a and 12b. The first sublayer 16 is located at a distance comprised between one third of the length Lg of the gate and two times the length Lg of the gate. In other words, the thickness of the first portion 12a of the buffer layer 12 is comprised between one third of the length Lg of the gate and two times the length Lg of the gate of the transistor.

In the present case, the buffer layer 12 comprises Ga-face gallium nitride GaN, and the first sublayer 16 comprises AlₓGa₁₋ₓN, the aluminum content x1 being higher than x+15%, the thickness t of the first sublayer 16 in the direction of the stack 10 being smaller than 20 nm. Other materials could be envisioned. However, indium gallium nitride InGaN, which is often cited, is not a good candidate. Specifically, it is difficult to grow InGaN comprising more than a few percent of indium with a satisfactory crystal quality. In addition, InGaN is grown at a temperature that is 200° C. lower than that required to grow GaN. Thus, it is difficult as a result to grow, on a layer of InGaN, a compound such as GaN with a good crystal quality without degrading the quality of the InGaN layer.

In the solution proposed in this patent, the growth temperatures of the various materials are quite close in order to allow the various layers of the stack to be produced with a sufficient crystal quality.

Because of the differences between the polarizations of the layers 12a and 16, a first fixed negative surface electric charge appears at the interface 17 located between the first portion of the buffer layer 12a and the first sublayer 16. In other words, a negative electric charge appears at the interface 17 and not in the bulk of the first sublayer 16 or in the first portion of the buffer layer 12a.

This solution in particular allows the thermal degradation of the transistor to be limited to a value lower than 2° C./mm/W and does not generate transconductance frequency dispersion (which is due to the use, according to the prior art, of deep centers to introduce negative charges into the buffer layer 12).

The two-dimensional electron gas 9 is thus confined to the channel and the mobile charges do not spread into the first portion of the buffer layer 12a.

By channel, what is meant is a layer of a thickness smaller than about 10 nm that is located on the surface of the buffer layer 12, in the vicinity of the heterojunction 15.

The small thickness of AlₓGa₁₋ₓN of the first sublayer 16 limits the increase in the thermal resistance of the transistor to a value lower than 2° C./mm/W.

Moreover, to prevent another electron gas from forming at the second interface 18 between the first sublayer 16 and the second portion of the buffer layer 12b, it is proposed, according to another aspect of the invention, to associate, with the first sublayer 16, a second sublayer 19 contiguous to the first sublayer 16, or, in other words, a second sublayer 19 that makes contact with the first sublayer 16 in order to form a second interface 18. The sum of the charges located in the vicinity of the second interface 18 between the first sublayer 16 and the second sublayer 19 is positive.

FIG. 11 illustrates this aspect of the invention.

The stack 10 comprises, as in FIG. 10, a buffer layer 12 that is separated into two portions 12a and 12b by a first sublayer 16. In the present case, the stack 10 furthermore comprises a second sublayer 19 comprising Alₓ₂Ga₁₋ₓ₂N, the aluminum content x₂ being lower than x+15%. Thus, the fact that the sum (of positive value) of the spontaneous and piezoelectric charges in the vicinity of the second interface 18 is lower than the sum (of negative value) of the spontaneous and piezoelectric charges of the first interface 17 allows a good confinement of electrons to the channel to be obtained while preventing a parasitic electron gas from forming at the interface 18, which would degrade the performance of the transistor in the microwave wavelength domain.

Since the thermal conductivity of AlGaN degrades greatly with aluminum concentration (it is divided by 4 for an aluminum content of 10%), it is proposed, to improve thermal resistance, to create an increasing aluminum concentration gradient that is oriented toward the first sublayer 16. With respect to a constant aluminum concentration, a linear aluminum concentration gradient allows the thermal resistance due to the second sublayer to be decreased by a factor of 3 to 4.

FIG. 12 illustrates aluminum-concentration profiles P1, P2 and P3 of the stack. The first sublayer 16 of small thickness, typically a thickness smaller than 20 nm, comprises a high aluminum content so as to improve the confinement of electrons to the channel in the vicinity of the heterojunction 15. From the first sublayer 16 to the second portion of the buffer layer 12b, the aluminum content in the profile P1 has a decreasing linear gradient, the aluminum content being comprised between x+0 and x+15%. The profiles P2 and P3 present other decreasing variations in the aluminum content over the secosublayer 19.

To compensate for the n-type doping of the AlGaN layer 19 induced by this concentration gradient, it is proposed, in one improvement to the invention, to introduce acceptor-type impurities into the AlGaN layer 19.

Advantageously, the impurities introduced into the second sublayer 19 are iron or carbon or magnesium or beryllium or any other atom known to be an acceptor center in GaN or AlGaN. The introduced impurity concentration is higher than or equal to the doping induced by this concentration gradient. This concentration gradient must be higher than or equal to the sum of the piezoelectric and spontaneous charges induced by the concentration gradient, divided by the thickness of the AlGaN layer 19.

FIG. 13 shows simulated log(I_{DS})=f(V_{GS}) transfer curves 61, 62, 63 and 64 for transistors according to the invention of 150 nm gate length Lg, for a voltage V_{DS}=40 V. The first sublayer 16 is located 100 nm from the heterojunction 15 and has a thickness t1 of 5 nm.

In the present case, the curves 61, 62, 63 and 64 each correspond to transistors in which the first sublayer 16 has a different aluminum content: 25, 30, 35 and 40%, respectively.

It may be seen that the subthreshold swing SS of each of the curves is about 70 mV per decade, close to its ideal value (60 mV/decade at room temperature). This value of 70 mV/decade is maintained over five current decades when the aluminum content is 40%, this allowing a leakage current lower than one μA/mm to be achieved and representing a real advantage for applications in which power consumption is an important criterion.

1. A field-effect transistor comprising a stack along a z-axis, comprising:
a barrier layer comprising a first semiconductor;
a heterojunction between said barrier layer and a buffer layer; and
a two-dimensional gas confined to a channel located in an xy-plane that lies perpendicular to the z-axis and in the vicinity of the heterojunction
the buffer layer comprising a second semiconductor comprising AlₓGa₍₁₋ₓ₎N being the aluminum content of said buffer layer,
wherein the stack furthermore comprises a first sublayer that divides the buffer layer into two portions and that comprises a third semiconductor comprising Alₓ₁Ga₍₁₋ₓ₁₎N, x₁ being higher than x+15%, x₁ being the aluminum content of said sublayer, so that the difference between the piezoelectric and spontaneous polarization coefficients of the second semiconductor and the third semiconductor induces, at a first interface between the first portion of the buffer layer and the first sublayer, a first fixed surface electric charge that generates an electric field that is directed along the z-axis and that is oriented toward the first interface, so as to allow the two-dimensional gas to be confined to the channel, the distance between the heterojunction and the first interface that is located between the first portion of the buffer layer and the first sublayer being comprised between one third of the length of the gate in the direction Ox perpendicular to the direction Oz of the stack of the transistor and two times the gate length.

2. The field-effect transistor as claimed in claim 1, wherein the two-dimensional gas is an electron gas, the fixed surface electric charge at the interface being negative.

3. The field-effect transistor as claimed in claim 1, wherein the second semiconductor is AlₓGa₍₁₋ₓ₎N with x=0%.

4. The field-effect transistor as claimed in claim 1, wherein the thickness of the first sublayer along the z-axis is smaller than 20 nm.

5. The field-effect transistor as claimed in claim 1, wherein the buffer layer further comprises a second sublayer that is located between the first sublayer and the second portion of the buffer layer, the second sublayer comprising Alₓ₂Ga₍₁₋ₓ₂₎N, and x₂ being lower than x+15%, a second fixed surface electric charge at the second interface formed between the first sublayer and the second sublayer being positive and lower, in absolute value, than the first fixed surface electric charge of the first interface.

6. The field-effect transistor as claimed in claim 5, wherein the thickness of the second sublayer in the direction of the stack is larger than or equal to 100 nm.

7. The field-effect transistor as claimed in claim 5, wherein the second AlGaN sublayer has an aluminum concentration gradient that increases in the direction of the stack and that is oriented toward the heterojunction, x₂ being comprised between 0 and 15%.

8. The field-effect transistor as claimed in claim 5, wherein the second sublayer further comprises acceptor-type impurities so as to compensate for the n-type doping induced by the aluminum concentration gradient of the second sublayer.

9. The field-effect transistor as claimed in claim 8, wherein the acceptor-type impurities introduced into the second sublayer are carbon or iron, beryllium or magnesium.
